(19) United States
(12) Patent Application Publication
(10) Pub. No.: US 2024/0258316 A1
(43) Pub. Date: Aug. 1, 2024

(54) SEMICONDUCTOR DEVICE

(71) Applicant: SAMSUNG ELECTRONICS CO., LTD., SUWON-SI (KR)

(72) Inventor: Kangyoo Song, Suwon-si (KR)

(21) Appl. No.: 18/417,254

(22) Filed: Jan. 19, 2024

(30) Foreign Application Priority Data
Jan. 26, 2023 (KR) 10-2023-0010240

(51) Int. Cl. H01L 27/092; H01L 21/8238; H01L 29/423

(52) U.S. Cl. CPC H01L 27/0922; H01L 21/82385; H01L 21/823878; H01L 29/42376

(57) ABSTRACT

Provided is a semiconductor device including a substrate having a first region and a second region spaced apart from each other, a plurality of first gate structures disposed in the first region, spaced apart from each other in a first horizontal direction, extending in a second horizontal direction perpendicular to the first horizontal direction, and having a first width, a plurality of second gate structures disposed in the second region, spaced apart from each other in the first horizontal direction, extending in the second horizontal direction, and having a second width greater than the first width, a plurality of single diffusion breaks arranged between the plurality of first gate structures and extending in the second horizontal direction, and a plurality of dummy diffusion breaks arranged between the first region and the second region, extending in the second horizontal direction, and including the same material as the single diffusion breaks.

### CROSS-REFERENCE TO RELATED APPLICATION

This application is based on and claims priority under 35 U.S.C. § 119 to Korean Patent Application No. 10-2023-0010240, filed on Jan. 26, 2023, in the Korean Intellectual Property Office, the contents of which are incorporated by reference herein in their entirety.

### BACKGROUND

The present disclosure relates to a semiconductor device, and more particularly, to a semiconductor device including a single diffusion break.

Semiconductor devices are provided to implement an integrated circuit (IC) chip on each package to qualify for use in various electronic products. Recently, the semiconductor integrated circuit (IC) industry has experienced an exponential growth. The advancements in the industry have resulted in requirements of ICs that have a reduced area and a more complex circuit than a previous generation.

Additionally, the development of semiconductor processes has resulted in semiconductor devices that may have high integration. However, the semiconductor devices may be required to have high performance. For example, small semiconductor devices may have a reduced area of integrated circuits while large semiconductor devices may have integrated circuits with high operating speed. That is, both high performance in the functions and a high operating speed are required for integrated circuits. Therefore, there is a need in the art for systems and methods to design semiconductor devices that include both high integration and performance.

### SUMMARY

According to an aspect of the present disclosure, there is provided a semiconductor device with reduced defects based on a dummy diffusion break as an etching stop layer in a region where a gate structure does not exist.

The embodiments of the present disclosure are not limited to the mentioned task, and other tasks not mentioned may be clearly understood by those of ordinary skill in the art from the following description.

The present disclosure provides a semiconductor device including a substrate having a first region and a second region spaced apart from each other, a plurality of first gate structures disposed in the first region, spaced apart from each other in a first horizontal direction, and extending in a second horizontal direction perpendicular to the first horizontal direction and having a first width, a plurality of second gate structures disposed in the second region, spaced apart from each other in the first horizontal direction, extending in the second horizontal direction and having a second width greater than the first width, a plurality of single diffusion breaks arranged between the plurality of first gate structures and extending in the second horizontal direction, and a plurality of dummy diffusion breaks arranged between the first region and the second region, extending in the second horizontal direction, and including the same material as the single diffusion breaks.

The present disclosure provides a semiconductor device including a substrate having a first region, a second region, and a dummy region arranged between the first region and the second region and divided into a plurality of zones, a plurality of first gate structures disposed in the first region, spaced apart from each other in a first horizontal direction, and extending in a second horizontal direction perpendicular to the first horizontal direction and having a first width, a plurality of second gate structures disposed in the second region, spaced apart from each other in the first horizontal direction, extending in the second horizontal direction and having a second width greater than the first width, a plurality of single diffusion breaks arranged between the plurality of first gate structures and extending in the second horizontal direction, and a plurality of dummy diffusion breaks arranged in the dummy region, extending in the second horizontal direction, and having different lengths in the second horizontal direction in the plurality of zones.

The present disclosure provides a semiconductor device including a substrate having a first region, a second region, and a dummy region arranged between the first region and the second region, a plurality of first active patterns disposed in the first region and extending in a first horizontal direction, a plurality of first gate structures disposed in the first region, extending in a second horizontal direction perpendicular to the first horizontal direction, and having a first width, wherein the plurality of first gate structures cross the first active patterns in the first region, a plurality of second active patterns disposed in the second region and extending in the first horizontal direction, a plurality of second gate structures disposed in the second region, extending in the second horizontal direction, and having a second width greater than the first width, wherein the plurality of second gate structures cross the second active patterns in the second region, a plurality of first recesses arranged between the plurality of first gate structures and spaced apart from each other in the first horizontal direction, a plurality of single diffusion breaks arranged in the plurality of first recesses and extending in the second horizontal direction, a plurality of dummy diffusion breaks arranged in the dummy region, extending in the second horizontal direction, and including the same material as the single diffusion breaks, and an interlayer insulating layer surrounding each of the first gate structures, the second gate structures, the single diffusion breaks, and the dummy diffusion breaks.

### BRIEF DESCRIPTION OF THE DRAWINGS

Embodiments of the present disclosure will be more clearly understood from the following detailed description taken in conjunction with the accompanying drawings:

FIG. 1 is a schematic diagram illustrating a semiconductor device according to an embodiment;

FIG. 2 is a cross-sectional view corresponding to part II of FIG. 1;

FIGS. 3A and 3B are graphs illustrating a relative etching rate based on the dummy diffusion breaks in a semiconductor device;

FIGS. 4 and 5 are cross-sectional views of a semiconductor device according to an embodiment;

FIG. 6 is a flowchart for a method of manufacturing a semiconductor device according to an embodiment;

FIGS. 7 to 11 are cross-sectional views illustrating a method of manufacturing a semiconductor device based on a process sequence according to an embodiment;

FIG. 12 is a schematic perspective view illustrating a semiconductor device according to an embodiment;

FIGS. 13 and 14 are cross-sectional views corresponding to an active pattern of the semiconductor device of FIG. 12; and

FIG. 15 is a block diagram illustrating a system including a semiconductor device according to an embodiment.

### DETAILED DESCRIPTION OF THE EMBODIMENTS

The present disclosure describes systems and methods for achieving high integration and performance in a semiconductor device. Embodiments of the disclosure describe a system that include a dummy diffusion break arranged on the semiconductor substrate as an etching stop layer. In some cases, the dummy diffusion break is used in a region of the substrate where a gate structure does not exist.

Due to the recent, fast-paced development of semiconductor processes, semiconductor devices may have a high integration but lack high performance. In some examples, a small semiconductor device may have a reduced area of the integrated circuits while a large semiconductor device may have a high operating speed of the integrated circuits. As a result, such devices may not be able to achieve both—high operating speed and high integration.

Embodiments of the present disclosure include systems and methods for achieving high integration and performance of semiconductor devices. In some cases, the semiconductor device includes a substrate having a first region and a second region spaced apart from each other. A plurality of first gate structures of a first width are spaced apart from each other in a first horizontal direction in the first region and extend in a second horizontal direction perpendicular to the first horizontal direction. Additionally, a plurality of second gate structures, having a second width greater than the first width, are spaced apart from each other in the first horizontal direction in the second region and extend in the second horizontal direction.

According to some embodiments, single diffusion breaks are arranged between the first gate structures and extend in the second horizontal direction. In some cases, dummy diffusion breaks are arranged between the first region and the second region and extend in the second horizontal direction. For example, the dummy diffusion breaks are made of the same material as the single diffusion breaks.

According to some embodiments, an empty space may be formed between regions having different gate structures. For example, the empty space may be formed when a gate structure is not placed. Accordingly, a dummy gate structure is formed in the empty space to minimize the density change of the gate structure in the semiconductor device. Such a dummy gate structure may serve as an etching stop layer, thus preventing over-etching from occurring in the interlayer insulating layer located in the empty space during an etching or polishing process.

One or more embodiments of the present disclosure include a design of forming dummy diffusion breaks (i.e., instead of dummy gate structures) in the empty space. In some cases, the dummy diffusion breaks may have sufficient etching selectivity for the interlayer insulating layer. Additionally, the dummy diffusion breaks may be formed together in the process of forming the single diffusion breaks and hence no additional process is required to form the dummy diffusion breaks. Accordingly, by using a dummy diffusion break as an etching stop layer in a region where a gate structure does not exist, embodiments of the present disclosure can improve defects due to steps in a subsequent process resulting in a high integration and a high operating speed of the semiconductor device.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. The features described herein may be embodied in different forms and are not to be construed as being limited to the example embodiments described herein. Rather, the example embodiments described herein have been provided merely to illustrate some of the many possible ways of implementing the methods, apparatuses, and/or systems described herein that will be apparent after an understanding of the disclosure of this application.

The present disclosure may be modified in multiple alternate forms, and thus specific embodiments will be exemplified in the drawings and described in detail. In the present specification, when a component (or a region, a layer, a portion, etc.) is referred to as being “on,” “connected to,” or “coupled to” another component, it means that the component may be directly disposed on/connected to/coupled to the other component, or that a third component may be disposed therebetween.

Like reference numerals may refer to like components throughout the specification and the drawings. It is noted that while the drawings are intended to illustrate actual relative dimensions of a particular embodiment of the specification, the present disclosure is not necessarily limited to the embodiments shown. The term “and/or” includes all combinations of one or more of which associated configurations may define.

It will be understood that, although the terms “first,” “second,” etc. may be used herein to describe various components, these components should not necessarily be limited by these terms. These terms are only used to distinguish one component from another. For example, a first component could be termed a second component, and, similarly, a second component could be termed a first component, without departing from the scope of the inventive concept. The terms of a singular form may include plural forms unless the context clearly indicates otherwise.

Additionally, terms such as “below,” “under,” “on,” and “above” may be used to describe the relationship between components illustrated in the figures. The terms are used as a relative concept and are described with reference to the direction indicated in the drawings. It should be understood that the terms “comprise,” “include,” or “have” are intended to specify the presence of stated features, integers, steps, operations, components, parts, or combinations thereof in the disclosure, but do not preclude the presence or addition of one or more other features, integers, steps, operations, components, parts, or combinations thereof.

In the present specification, although terms such as first and second are used to describe various elements or components, it goes without saying that these elements or components are not limited by these terms. These terms are only used to distinguish a single element or component from other elements or components. Therefore, it goes without saying that a first element or component referred to below may be a second element or component within the technical idea of the present invention.

Hereinafter, a method for achieving high operating speed and high integration of a semiconductor device of the embodiments of the present disclosure will be described in detail with reference to the accompanying drawings. The same reference numerals are used for the same components in the drawings, and duplicate descriptions thereof are omitted.

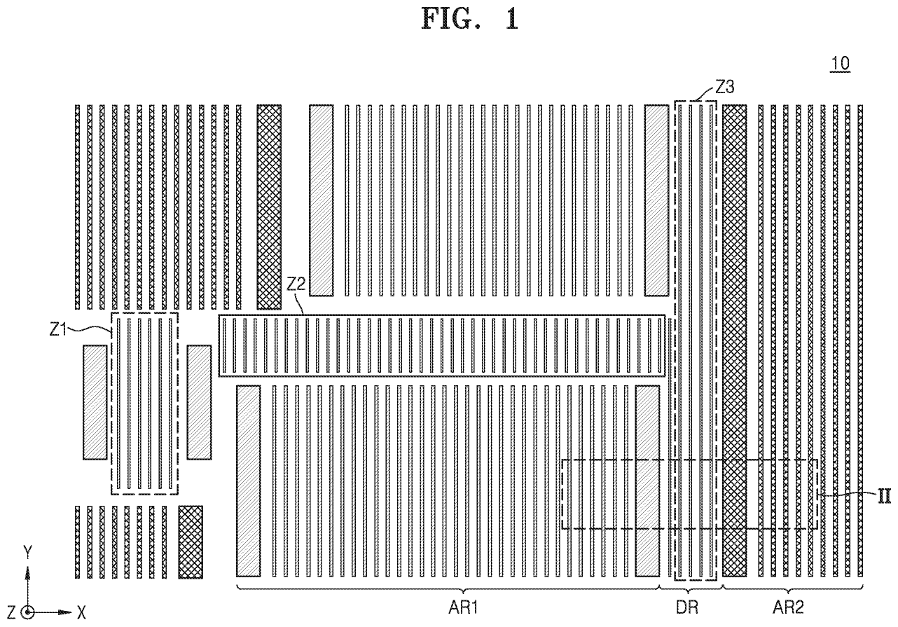

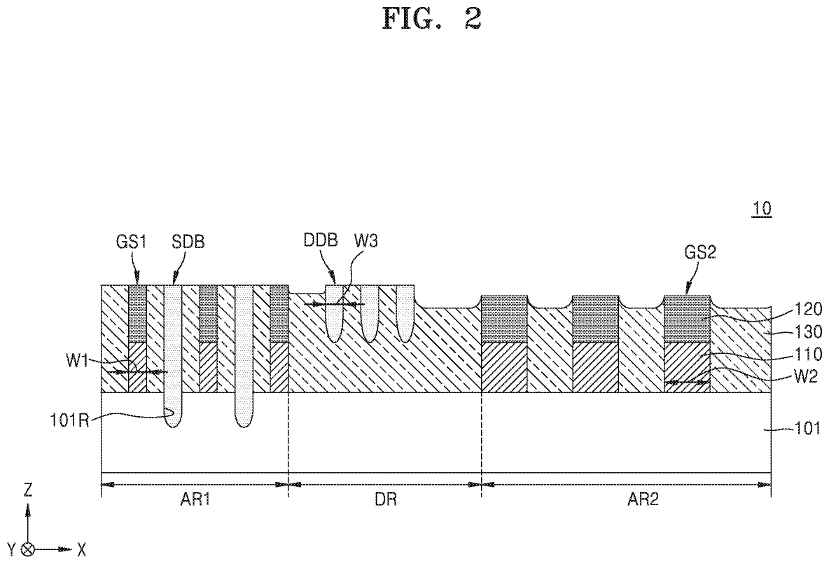

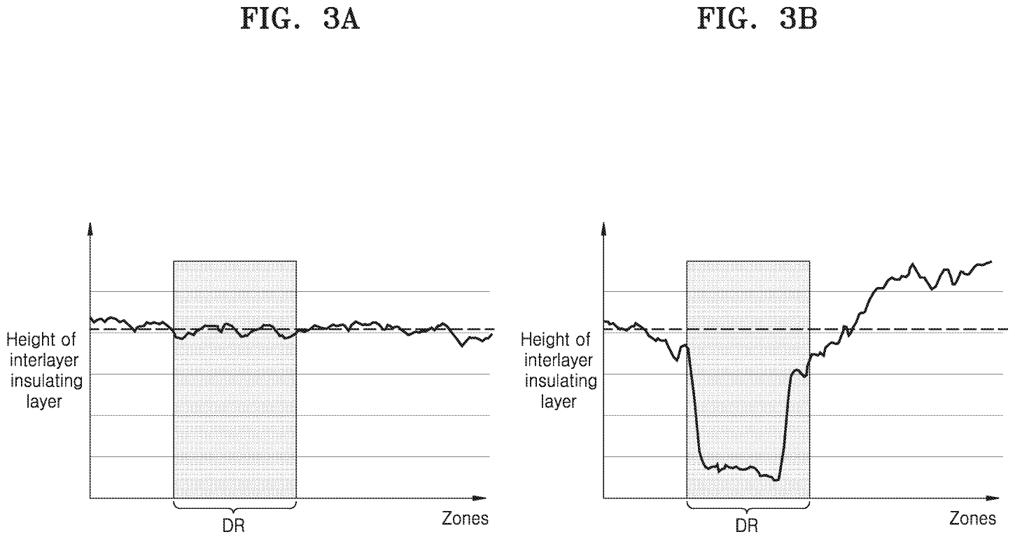

FIG. 1 is a schematic diagram illustrating a semiconductor device according to an embodiment, FIG. 2 is a cross-sectional view corresponding to part II of FIG. 1, and FIGS. 3A and 3B are graphs illustrating a relative etching rate based on the dummy diffusion breaks in a semiconductor device. For convenience of description, FIG. 2 illustrates only the main components of FIG. 1.

Referring to FIGS. 1 and 2, a semiconductor device 10 includes first and second gate structures GS1 and GS2, single diffusion breaks SDB, dummy diffusion breaks DDB, and an interlayer insulating layer 130 which are arranged on a substrate 101.

The substrate 101 may be a wafer including silicon (Si). According to some embodiments, the substrate 101 may be a wafer including a semiconductor element such as germanium (Ge) or a compound semiconductor such as silicon carbide (SiC), gallium arsenide (GaAs), or indium phosphide (InAs). In some cases, the substrate 101 may have a silicon on insulator (SOI) structure. Additionally, the substrate 101 may include a conductive area, for example, a well doped with impurities or a structure doped with impurities.

The substrate 101 may include a first region AR1, a second region AR2, and a dummy region DR arranged between the first region AR1 and the second region AR2. The first region AR1 and the second region AR2 may be regions in which the first and second gate structures GS1 and GS2 are arranged. The dummy region DR may be a region in which the dummy structure (e.g., DDB) is arranged.

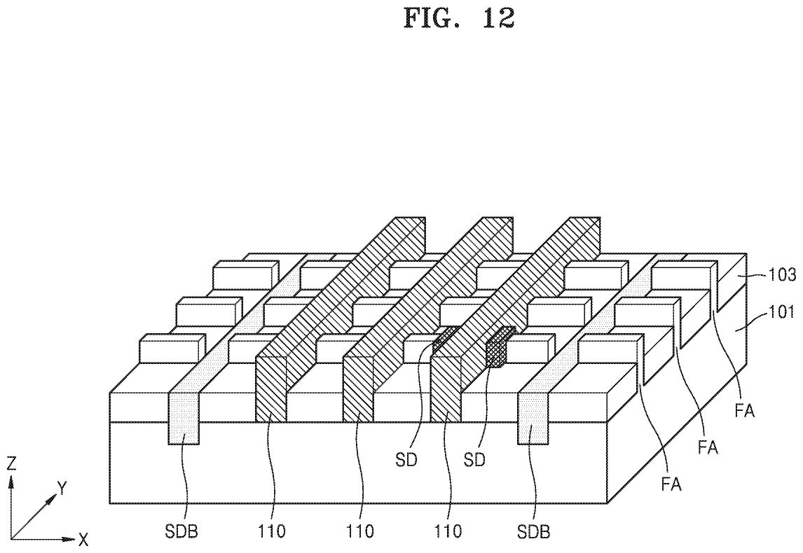

The first and second gate structures GS1 and GS2 may be spaced apart from each other in a first horizontal direction (i.e., X direction) on the first region AR1 and the second region AR2, respectively. Each of the first and second gate structures GS1 and GS2 may extend in a second horizontal direction (i.e., Y direction). Additionally, the first and second gate structures GS1 and GS2 may be arranged on an active pattern FA (as described with reference to FIG. 12) and a device isolation layer 103 (as described with reference to FIG. 12) in the first and second regions AR1 and AR2.

The first gate structure GS1 of the first region AR1 may have a first width W1 and the second gate structure GS2 of the second region AR2 may have a second width W2. In some cases, the second width W2 may be greater than the first width W1. That is, the first gate structure GS1 and the second gate structure GS2 have different sizes and may perform different operations.

Each of the first and second gate structures GS1 and GS2 may include a gate electrode 110, a gate dielectric layer, and a gate capping layer 120. The gate electrode 110 may be stacked in a single layer or two or more layers. According to some embodiments, the gate electrode 110 may include a work function control layer and a central electrode layer, respectively. The work function control layer may serve to adjust the work function and the central electrode layer may serve to fill a space formed by the work function control layer. The work function control layer may include, for example, at least one of TiN, WN, TiAl, TiAlN, TaN, TiC, TaC, TaCN, TaSiN, and a combination thereof. Additionally, the central electrode layer may include at least one of W, Al, Co, Ti, Ta, poly-Si, SiGe, and a metal alloy.

In some cases, the gate dielectric layer may be arranged between the gate electrode 110 and the active pattern FA. Additionally, the gate dielectric layer may be disposed between the gate electrode 110 and the device isolation layer 103. The gate dielectric layer may extend in the second horizontal direction (i.e., Y direction) along the profile of the active pattern FA protruding above the device isolation layer 103. According to some embodiments, the gate electrode 110 and the gate dielectric layer may be formed through a replacement process or a gate last process. The replacement process or the gate last process refers to whether the metal electrode is deposited before or after the high temperature activation anneals of the flow. In some cases, the gate last process is referred to as the replacement metal gate process.

The gate dielectric layer may include a high dielectric material having a higher dielectric constant than silicon oxide. For example, the gate dielectric layer may include HfO₂, ZrO₂, LaO, Al₂O₃, Ta₂O₅, and the like.

The gate capping layer 120 may extend on the gate electrode 110 in the second horizontal direction (i.e., Y direction). The gate capping layer 120 may include, for example, at least one of silicon nitride, silicon oxynitride, and silicon oxycarbonitride.

The height of the gate capping layer 120 in the first area AR1 in the vertical direction (i.e., Z direction) may be greater than the height of the gate capping layer 120 in the second area AR2 in the vertical direction (i.e., Z direction). Thus, the top surface of the gate capping layer 120 of the first region AR1 may be at a higher level than the top surface of the gate capping layer 120 of the second region AR2. However, the embodiments are not limited thereto, and the top surface of the gate capping layer 120 in the first area AR1 may be at substantially the same level as the top surface of the gate capping layer 120 in the second area AR2.

The source/drain regions SD (referring to FIG. 12) may be arranged at both sides of each of the first and second gate structures GS1 and GS2. The source/drain region SD may be arranged in the active pattern FA. That is, the source/drain region SD may be formed in a region in which the active pattern FA is partially etched. According to some embodiments, the source/drain region SD may be an elevated source/drain region. Accordingly, the top surface of the source/drain region SD may be higher than the top surface of the active pattern FA.

According to some embodiments of the present disclosure, when the semiconductor device 10 is a pMOS transistor, the source/drain region SD may include a compression strain material. For example, the compression strain material may be a material having a higher lattice constant than silicon (Si), such as silicon germanium (SiGe). The compression strain material may apply compression stress to the active pattern FA under the first and second gate structures GS1 and GS2 to enhance carrier mobility in a channel region.

According to some embodiments, when the semiconductor device 10 is an nMOS transistor, the source/drain region SD may include the same material as the substrate 101 or a tensile strain material. In some examples, the tensile strain material may be a material having a lower lattice constant than silicon (Si), for example, silicon carbide (SiC). The tensile strain material may apply tensile stress to the active pattern FA under the first and second gate structures GS1 and GS2 to enhance carrier mobility in the channel region.

The interlayer insulating layer 130 may be arranged on the source/drain region SD and the device isolation layer 103. Additionally, the interlayer insulating layer 130 may be formed to contact the outer walls of the first and second gate structures GS1 and GS2. The interlayer insulating layer 130 is an insulating material and may include at least one of, for example, silicon oxide, silicon nitride, silicon oxynitride, and low dielectric material. The uppermost surface of the interlayer insulating layer 130 may be formed in a flat shape, or may be formed to substantially have a partial step due to a difference in the shapes of structures arranged in the first region AR1, the second region AR2, and the dummy region DR.

The single diffusion break SDB may be arranged between the first region AR1 and the first gate structure GS1. In the semiconductor device 10, a standard cell is a unit of a layout included in an integrated circuit. The boundary of the standard cell may be determined by a cell isolation layer. The cell isolation layer may be inserted to reduce an influence between adjacent standard cells, for example, a local layout effect (LLE). The cell isolation layer may separate the active pattern FA between neighboring cells and may be filled with an insulating material. According to some embodiments, the cell isolation layer may separate the source/drain region SD between neighboring cells by removing at least a portion of the source/drain region SD and/or the active pattern FA. In some cases, the cell isolation layer may refer to a single diffusion break SDB.

The single diffusion break SDB may extend in the vertical direction (i.e., Z direction) to penetrate the interlayer insulating layer 130 and fill a first recess 101R inside the substrate 101. In some cases, the single diffusion break SDB may be formed by a replication process in a place where a gate electrode 110 is located to separate the source/drain region SD between adjacent cells.

The dummy diffusion breaks DDB may be arranged in the dummy region DR. Here, a third width W3 in the first horizontal direction (i.e., X direction) of each of the dummy diffusion breaks DDB may be constant. The intervals of the dummy diffusion breaks DDB in the first horizontal direction (i.e., X direction) may be constant. In addition, the length of each of the dummy diffusion breaks DDB in the vertical direction (i.e., Z direction) may be constant. According to some embodiments, the dummy region DR may be divided into a plurality of zones. For example, the dummy region DR may be divided into a first zone Z1, a second zone Z2, and a third zone Z3, but embodiments are not limited thereto. In each of the first to third zones Z1, Z2 and Z3, the dummy diffusion breaks DDB may be formed to have different lengths in the second horizontal direction (i.e., Y direction). For example, the horizontal lengths of the dummy diffusion breaks DDB may vary depending on the positions and sizes of the first to third zones Z1, Z2, and Z3.

The single diffusion breaks SDB and the dummy diffusion breaks DDB may be formed of substantially the same material. The interlayer insulating layer 130 is placed around the single diffusion breaks SDB and the dummy diffusion breaks DDB. In some cases, the interlayer insulation layer 130 may surround the single diffusion breaks SDB and the dummy diffusion breaks DDB. In some examples, the interlayer insulation layer 130 may contact the single diffusion breaks SDB and the dummy diffusion breaks DDB on both sides (i.e., as shown in FIGS. 2 and 4-5). In some examples, the interlayer insulation layer 130 may contact the single diffusion breaks SDB and the dummy diffusion breaks DDB on each of the four sides, i.e., in a plan view. In some cases, the material of the single diffusion breaks SDB and the dummy diffusion breaks DDB may have an etching selectivity for the material of the interlayer insulating layer 130. For example, both the single diffusion breaks SDB and the dummy diffusion breaks DDB may include silicon nitride and the interlayer insulating layer 130 may include silicon oxide.

Etching is used in microfabrication to chemically remove layers from the surface of a wafer during a manufacturing process. In some cases, for an etch step, part of the wafer is protected from the etchant by a masking material which resists etching. Etching may be orientation-dependent and considers an etch rate. For example, at a low temperature, etching rate is slow (and etching selectivity is high) and at a high temperature, etching rate is high (and etching selectivity is low). That is, by increasing the temperature, the etch rate increases, but the selectivity decreases. The etching selectivity refers to a ratio of the etch rates between materials. In some examples, dummy diffusion breaks DDB may have an etch rate that is lower than the etch rate of the interlayer insulating layer 130.

One or more embodiments of the present disclosure include a comparison between the single diffusion breaks SDB and the dummy diffusion breaks DDB in the semiconductor device. For example, the width of each of the single diffusion breaks SDB (W1) in the first horizontal direction (i.e., X direction) may be the same as the third width W3 of each of the dummy diffusion breaks DDB. However, the length of each of the single diffusion breaks SDB in the vertical direction (i.e., Z direction) may be greater than the length of each of the dummy diffusion breaks DDB in the vertical direction (i.e., Z direction). That is, the level of the top surface of the single diffusion breaks SDB is substantially the same as the level of the top surface of the dummy diffusion breaks DDB. The level of the bottom surface of the single diffusion breaks SDB may be lower than the level of the top surface of the substrate 101 and the level of the bottom surface of the dummy diffusion breaks DDB may be higher than the level of the top surface of the substrate 101.

One or more embodiments of the present disclosure include a comparison of the first and second gate structures GS1 and GS2 and the dummy diffusion breaks DDB in the semiconductor device. The dummy diffusion breaks DDB may be formed of substantially the same material as the gate capping layer 120 positioned above the first and second gate structures GS1 and GS2. Moreover, the level of the top surface of the first gate structure GS1 may be substantially the same as the level of the top surface of the dummy diffusion breaks DDB. In some cases, the level of the top surface of the second gate structure GS2 may be lower than the level of the top surface of the dummy diffusion breaks DDB.

Recently, due to the development of semiconductor processes, semiconductor devices may be required to have high integration and high performance. For example, small semiconductor devices may reduce the area of integrated circuits and large semiconductor devices may enable the increase of the operating speed of integrated circuits. Therefore, it is important to design semiconductor devices in consideration of both integration and performance to achieve the functions and operating speed required for integrated circuits.

In some cases, an empty space in which a gate structure is not placed may be positioned between regions in which gate structures having different structures are placed. In some cases, a dummy gate structure is formed in the empty space to minimize the density change of the gate structure in the semiconductor device. Such a dummy gate structure may serve as an etching stop layer, preventing over-etching from occurring in the interlayer insulating layer located in the empty space during an etching or polishing process. However, designing dummy gate structures in empty spaces is challenging when the integration of semiconductor devices is high.

Therefore, the semiconductor device 10 of the present embodiment adopted a design of forming dummy diffusion breaks DDB instead of dummy gate structures in an empty space. In some cases, the dummy diffusion breaks DDB may include substantially the same material as the gate capping layers 120 located above the first and second gate structures GS1 and GS2, and thus may have a sufficient etching selectivity for the interlayer insulating layer 130. Additionally, since the dummy diffusion breaks DDB may be formed together in the process of forming the single diffusion breaks SDB, no additional process is required to form the dummy diffusion breaks DDB.

The step of the interlayer insulating layer 130 may be validated based on experimental examples of different structures in case of forming dummy diffusion breaks DDB in the dummy region DR (the hatched part of the graph) (e.g., FIG. 3A) and not forming dummy diffusion breaks DDB in the dummy region DR (e.g., FIG. 3B).

Referring to FIGS. 3A and 3B, when the dummy diffusion breaks DDB are formed (i.e., FIG. 3A), the step in the dummy region DR and the steps in other parts may be maintained at a certain level. In some cases, when the dummy diffusion breaks DDB are not formed (FIG. 3B), the step in the dummy region DR is rapidly changed.

That is, using the dummy diffusion breaks DDB as an etching stop layer with an etching selectivity for the interlayer insulating layer 130 in the dummy region DR may prevent over-etching in the interlayer insulating layer 130 located in the dummy region DR during the etching or polishing process.

According to embodiments of the present disclosure, the semiconductor device may efficiently manage the step of the interlayer insulating layer 130 in the subsequent etching or polishing process by using the dummy diffusion breaks DDB in the region as the etching stop layer where the first and second gate structures GS1 and GS2 do not exist and may provide an effect of solving a defect due to the step.

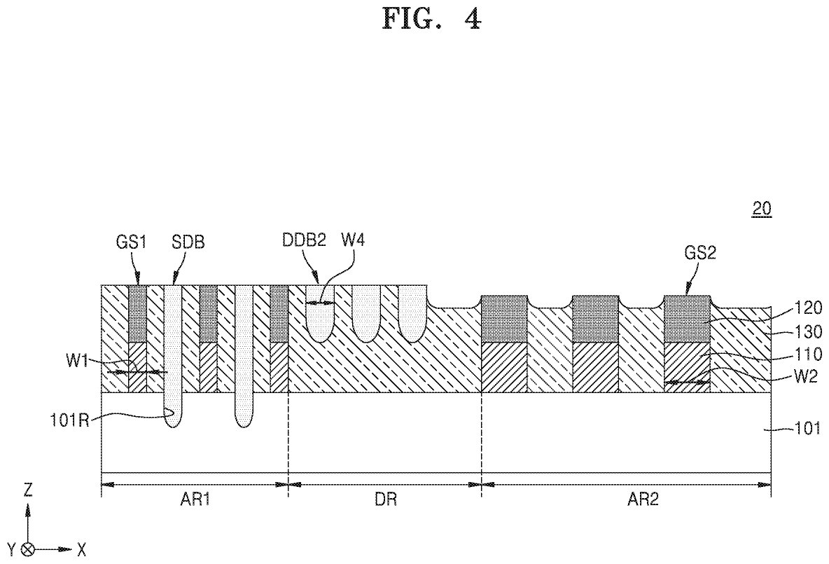

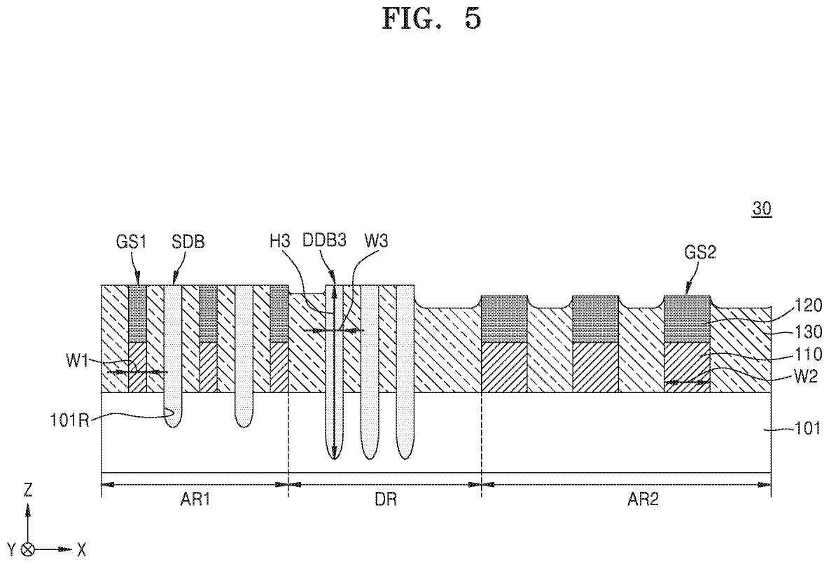

FIGS. 4 and 5 are cross-sectional views of a semiconductor device according to an embodiment.

In some cases, components of the semiconductor devices 20 and 30 and materials of the components are substantially the same as or similar to those described above with reference to FIGS. 1 to 3. Therefore, for convenience of description, repeated descriptions are omitted and differences from the semiconductor device 10 are provided.

Referring to FIG. 4, a semiconductor device 20 includes first and second gate structures GS1 and GS2, single diffusion breaks SDB, dummy diffusion breaks DDB2, and an interlayer insulating layer 130 which are arranged on a substrate 101.

A fourth width W4 in the first horizontal direction (i.e., X direction) of each of the dummy diffusion breaks DDB2 in the semiconductor device 20 may be constant. Additionally, the length of each of the dummy diffusion breaks DDB2 in the vertical direction (i.e., Z direction) may be constant.

One or more embodiments of the present disclosure include a comparison between the single diffusion breaks SDB and the dummy diffusion breaks DDB2 in the semiconductor device. The width of each of the single diffusion breaks SDB in the first horizontal direction (i.e., X direction) may be less than the fourth width W4 of each of the dummy diffusion breaks DDB2. That is, during the etching process of the trenches in which the single diffusion breaks SDB and the dummy diffusion breaks DDB2 are placed, the degrees of etching according to the first horizontal direction (i.e., X direction) may differ based on the presence of the first gate structure GS1 in the first region AR1 and the dummy region DR. However, the length of each of the single diffusion breaks SDB in the vertical direction (i.e., Z direction) may be greater than the length of each of the dummy diffusion breaks DDB2 in the vertical direction (i.e., Z direction).

Referring to FIG. 5, a semiconductor device 30 includes first and second gate structures GS1 and GS2, single diffusion breaks SDB, dummy diffusion breaks DDB3, and an interlayer insulating layer 130 which are arranged on a substrate 101.

A third width W3 in the first horizontal direction (i.e., X direction) of each of the dummy diffusion breaks DDB3 in the semiconductor device 30 may be constant. Additionally, the length H3 of each of the dummy diffusion breaks DDB3 in the vertical direction (i.e., Z direction) may be constant.

One or more embodiments of the present disclosure include a comparison between the single diffusion breaks SDB and the dummy diffusion breaks DDB3 in the semiconductor device. The length of each of the single diffusion breaks SDB in the vertical direction (i.e., Z direction) may be less than the length H3 of each of the dummy diffusion breaks DDB3. That is, the level of the top surface of the single diffusion breaks SDB is substantially the same as the level of the top surface of the dummy diffusion breaks DDB3. Additionally, the level of the bottom surface of the single diffusion breaks SDB may be lower than the level of the top surface of the substrate 101 and the level of the bottom surface of the dummy diffusion breaks DDB3 may be lower than the level of the top surface of the substrate 101. Thus, during the etching process of the trenches in which the single diffusion breaks SDB and the dummy diffusion breaks DDB3 are placed, the degrees of etching according to the vertical direction (i.e., Z direction) may differ depending on the presence of the first gate structure GS1 in the first region AR1 and the dummy region DR. In some cases, the width of each of the single diffusion breaks SDB in the first horizontal direction (i.e., X direction) may be the same as the third width W3 of each of the dummy diffusion breaks DDB3.

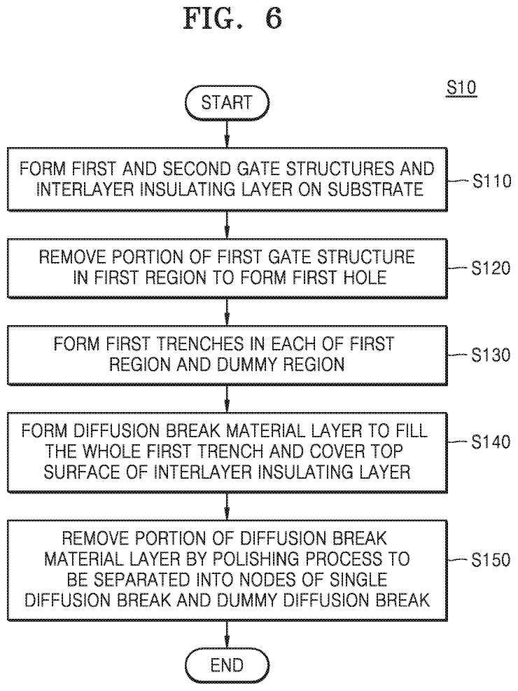

FIG. 6 is a flowchart illustrating a method of manufacturing a semiconductor device according to an embodiment.

Referring to FIG. 6, the method S10 of manufacturing a semiconductor device may include a process sequence of first to fifth operations S110 to S150.

While some embodiments are implemented differently, a specific process sequence may be performed differently from the sequence described. For example, the two processes described continuously may be performed substantially simultaneously or in the opposite sequence to the sequence described.

The method (S10) of manufacturing a semiconductor device includes a first operation (S110) of forming first and second gate structures and an interlayer insulating layer on a substrate, a second operation (S120) of forming a first hole by removing a portion of the first gate structure in a first region, a third operation (S130) of forming a first trench in each of the first region and a dummy region, a fourth operation (S140) of forming a diffusion break material layer to fill the whole first trench and cover the top surface of the interlayer insulating layer, and a fifth operation (S150) of removing a portion of the diffusion break material layer by a polishing process to separate the diffusion break material layer into nodes of a single diffusion break and a dummy diffusion break.

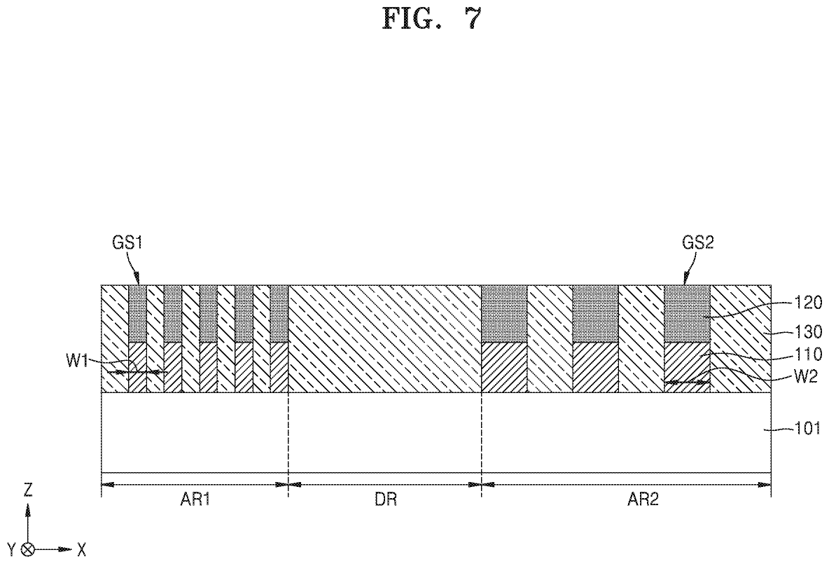

Technical features of the first to fifth operations S110 to S150 will be described in detail with reference to FIGS. 7 to 11.

FIGS. 7 to 11 are cross-sectional views illustrating a method of manufacturing a semiconductor device based on a process sequence according to an embodiment.

Referring to FIG. 7, a substrate 101 including a first region AR1, a second region AR2, and a dummy region DR arranged between the first region AR1 and the second region AR2 may be prepared.

In some cases, a partial region of the substrate 101 may be etched to form an active pattern FA (refer to FIG. 12) protruding in a vertical direction (i.e., Z direction) and extending in a first horizontal direction (i.e., X direction) from the top surface of the substrate 101.

After forming an insulating layer covering the active pattern FA on the substrate 101, the insulating layer may be etched to form a device isolation layer 103 (refer to FIG. 12). The active pattern FA may be formed to protrude above the top surface of the device isolation layer 103 and be exposed.

First and second gate structures GS1 and GS2 which intersect the active pattern FA on the substrate 101 and extend in a second horizontal direction (i.e., Y direction) are formed. The first gate structure GS1 having a first width W1 may be formed in the first region AR1 and the second gate structure GS2 having a second width W2 may be formed in the second region AR2.

Each of the first and second gate structures GS1 and GS2 may include a gate dielectric layer, a gate electrode 110, and a gate capping layer 120, which are sequentially stacked on the active pattern FA. According to some embodiments, the gate dielectric layer may include silicon oxide, the gate electrode 110 may include metal, and the gate capping layer 120 may include silicon nitride.

The source/drain region SD may be formed by an epitaxial growth process on the active pattern FA exposed from both sides of each of the first and second gate structures GS1 and GS2.

The first and second gate structures GS1 and GS2 may be spaced apart from each other in a first horizontal direction (i.e., X direction) on the first region AR1 and the second region AR2 and may extend in a second horizontal direction (i.e., Y direction). Additionally, the first and second gate structures GS1 and GS2 may be arranged on an active pattern FA and a device isolation layer 103 in the first and second regions AR1 and AR2.

The first gate structure GS1 of the first region AR1 may have a first width W1 and the second gate structure GS2 of the second region AR2 may have a second width W2. In some cases, the second width W2 may be greater than the first width W1.

According to some embodiments, the interlayer insulating layer 130 may be formed to cover both sides of the first and second gate structures GS1 and GS2. The interlayer insulating layer 130 may include silicon oxide. Subsequently, a process of flattening the interlayer insulating layer 130 may be performed until the top surface of the gate capping layer 120 is exposed.

According to some embodiments, the first and second gate structures GS1 and GS2 may be formed through a replacement process or a gate last process.

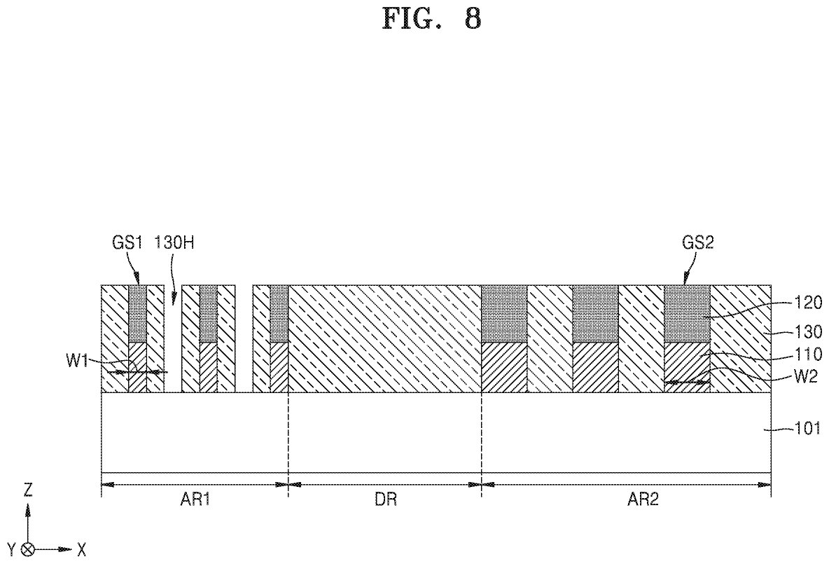

Referring to FIG. 8, a portion of the first gate structure GS1 may be removed from the first region AR1 to form a first hole 130H.

The portion of the first gate structure GS1 may be removed to form the first hole 130H exposing the top surface of the substrate 101 in the interlayer insulating layer 130. The first holes 130H may be formed in the first region AR1 through a photograph process and an etching process of selectively removing some parts of the first gate structure GS1.

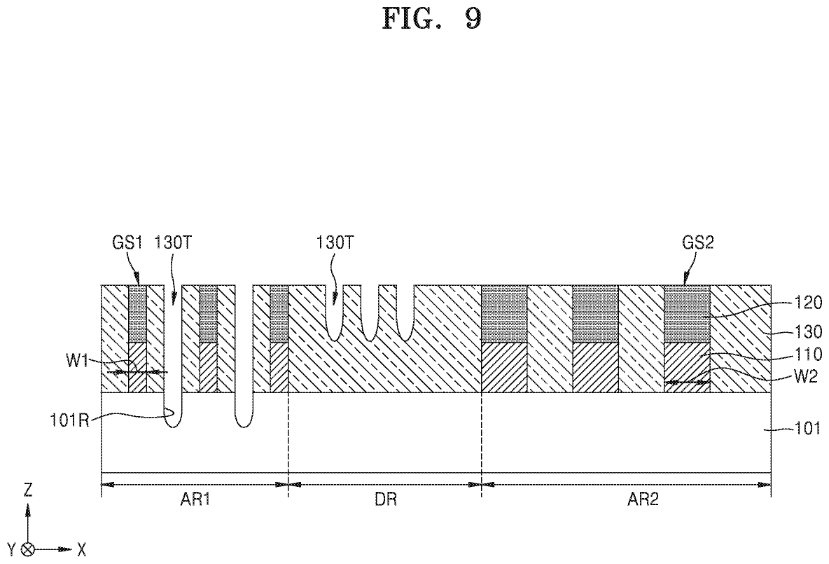

Referring to FIG. 9, first trenches 130T may be formed in each of the first region AR1 and the dummy region DR.

In the first region AR1, the first trench 130T may be formed through an etching process that extends the first hole 130H (referring to FIG. 8) into the substrate 101. Accordingly, a first recess 101R may be formed under the first trench 130T in the first region AR1. That is, the etching process in the first region AR1 may be etching with respect to the substrate 101.

In some cases, the first trench 130T in the dummy region DR may be concurrently formed through an etching process extending into the interlayer insulating layer 130. That is, the etching process in the dummy region DR may be etching the interlayer insulating layer 130.

Accordingly, since the materials etched in the first region AR1 and the dummy region DR are different, the first trench 130T in the first region AR1 and the first trench 130T in the dummy region DR may have different depths. According to the characteristics of a dry etching process, the first trench 130T may have a tapered shape of which the width becomes narrower toward the lower portion, but the embodiments are not limited thereto.

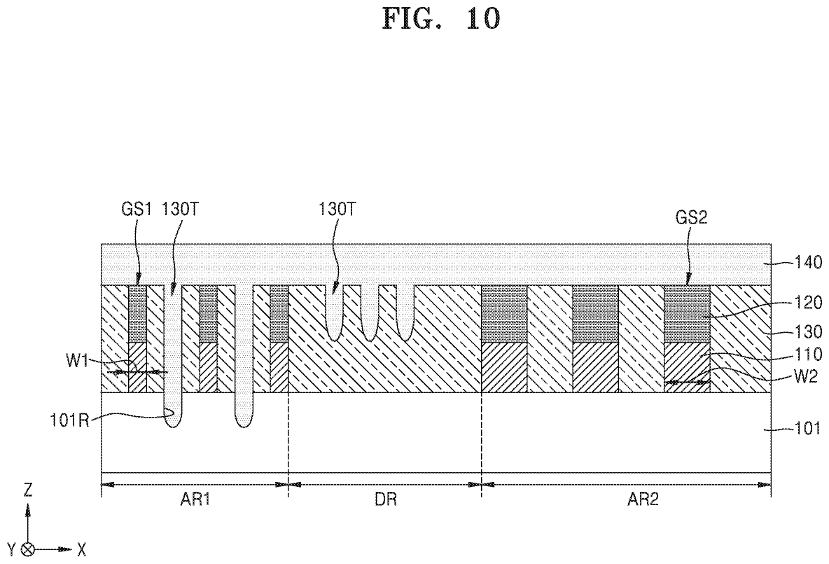

Referring to FIG. 10, a diffusion break material layer 140 may be formed to fill the whole first trench 130T and cover the top surface of the interlayer insulating layer 130.

The diffusion break material layer 140 may cover both the first trenches 130T arranged in the first region AR1 and the first trenches 130T arranged in the dummy region DR and may be formed to have sufficient thickness to completely cover the interlayer insulating layer 130. The diffusion break material layer 140 may be formed by a Chemical Vapor Deposition (CVD) process, a Physical Vapor Deposition (PVD) process, or an Atomic Layer Deposition (ALD) process.

Physical vapor deposition (PVD) includes multiple vacuum deposition methods which can be used to produce thin films and coatings on substrates including metals, ceramics, glass, and polymers. PVD refers to a process in which a material transitions from a condensed phase to a vapor phase and then back to a thin film condensed phase. For example, common PVD processes are sputtering and evaporation. For example, PVD is used in the manufacturing of items with thin films for optical, mechanical, electrical, acoustic or chemical functions.

Chemical vapor deposition (CVD) is a vacuum deposition method used to produce high-quality, and high-performance, solid materials. In a typical CVD process, the wafer (or the substrate) is exposed to one or more volatile precursors. The precursors react and/or decompose on the substrate surface to produce the desired deposition layer. In some cases, several volatile by-products are also produced which are removed by gas flowing through the reaction chamber.

Atomic layer vapor deposition (ALD) is a thin-film deposition technique based on the sequential use of a gas-phase chemical process. The ALD method is a subclass of chemical vapor deposition. In some cases, the ALD reactions use two chemicals called precursors (or reactants). The precursors react with the surface of a material in a sequential, self-limiting manner. A thin film is slowly deposited through repeated exposure to separate precursors. For example, a film is grown on a substrate by exposing the surface to alternate gaseous species. The maximum amount of material deposited on the surface after a single exposure to the precursors (i.e., an atomic layer vapor deposition cycle) is determined based on the nature of the precursor-surface interaction. Accordingly, by varying the number of cycles, the ALD technique can grow materials uniformly and with high precision on arbitrarily complex and large substrates.

The material of the diffusion break material layer 140 may have an etching selectivity with respect to the material of the interlayer insulating layer 130. For example, the diffusion break material layer 140 may include silicon nitride and the interlayer insulating layer 130 may include silicon oxide.

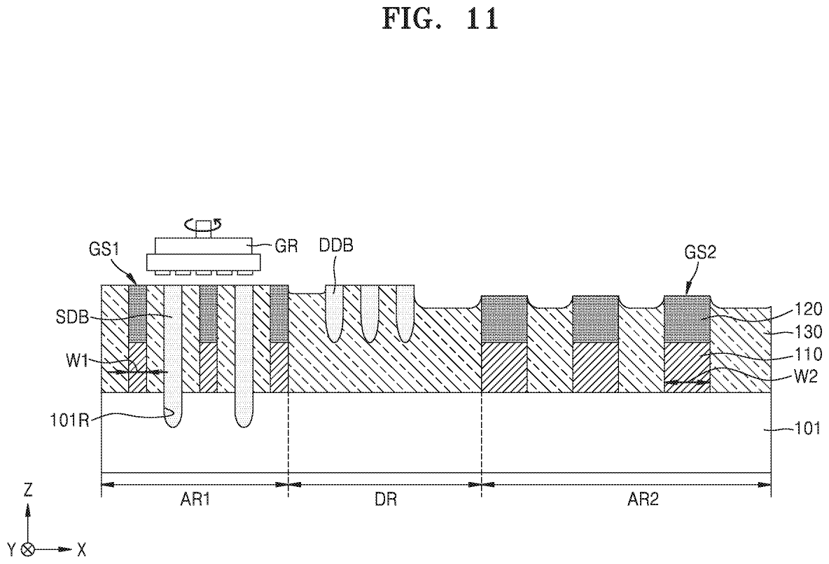

Referring to FIG. 11, a diffusion break material layer 140 (referring to FIG. 10) is removed from a top surface of the interlayer insulating layer 130.

The polishing process is performed using a grinder GR. The polishing process may be a chemical mechanical polishing process. The grinder GR may remove a part of the diffusion break material layer 140 (referring to FIG. 10) from the top surface of the interlayer insulating layer 130 using a polishing process such that the top surfaces of the first and second gate structures GS1 and GS2 are exposed.

Additionally, the diffusion break material layer 140 (in FIG. 10) may be separated into nodes of single diffusion breaks SDB and dummy diffusion breaks DDB by the polishing process. Thus, the dummy diffusion breaks DDB may be formed in the dummy region DR to serve as an etching stop layer.

The first gate structure GS1 of the first region AR1 may have a first width W1 and the second gate structure GS2 of the second region AR2 may have a second width W2. In some cases, the second width W2 may be greater than the first width W1. That is, the first gate structure GS1 and the second gate structure GS2 have different sizes, resulting in a difference in the degrees of polishing, so the height of the gate capping layer 120 of the first region AR1 in the vertical direction (i.e., Z direction) may be greater than the height of the gate capping layer 120 of the second region AR2 in the vertical direction (i.e., Z direction). However, the embodiments are not limited thereto.

Referring again to FIG. 6, in the method (S10) of manufacturing the semiconductor device, the step of the interlayer insulating layer 130 may be efficiently managed in the subsequent etching or polishing process by using, as the etching stop layer, the dummy diffusion breaks DDB in the region where the first and second gate structures GS1 and GS2 do not exist and may provide an effect of solving a defect due to the step.

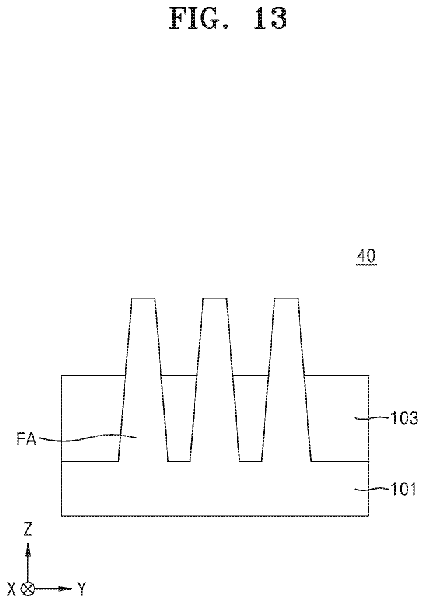

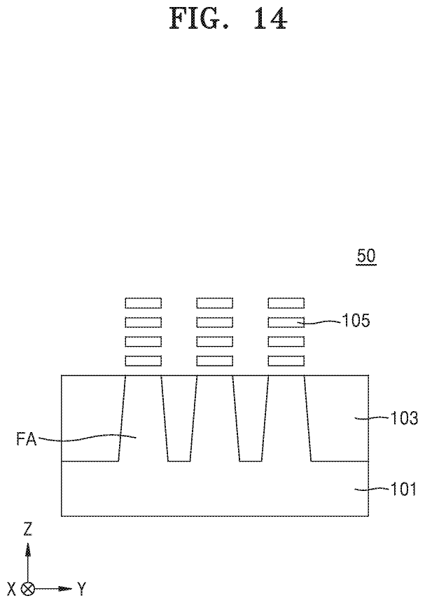

FIG. 12 is a perspective view illustrating a semiconductor device according to an embodiment and FIGS. 13 and 14 are cross-sectional views corresponding to an active pattern of the semiconductor device of FIG. 12. For convenience of description, only some components of the first region AR1 (in FIG. 2) of the substrate 101 are illustrated in FIGS. 12 to 14 and repeated descriptions are omitted for brevity.

Referring to FIGS. 12 to 14, at least one active pattern FA may extend in the first horizontal direction (i.e., X direction) from the substrate 101, and the active pattern FA may cross the gate electrode 110 extending in the second horizontal direction (i.e., Y direction) to form a transistor.

The gate electrode 110 may be spaced apart from each other in the first horizontal direction (i.e., X direction) on the substrate 101 and may extend in the second horizontal direction (i.e., Y direction). Additionally, the gate electrode 110 may be disposed on the active pattern FA and the device isolation layer 103 on the substrate 101.

The single diffusion breaks SDB may be spaced apart on the substrate 101 in the first horizontal direction (i.e., X direction) and may extend in the second horizontal direction (i.e., Y direction). Additionally, the single diffusion breaks SDB may penetrate the device isolation layer 103 and extend into the substrate 101 to cut the source/drain region SD and/or the active pattern FA.

Referring to FIG. 13, when the fin-shaped active pattern FA extends in the first horizontal direction (i.e., X direction) in a semiconductor device 40, a transistor formed by the active pattern FA and the gate electrode 110 may be referred to as a fin-type field effect transistor (FinFET). However, the embodiments are described by referring to the semiconductor device 40 as including FinFET, but they may be applied to transistors with a structure different from the FinFET.

Referring to FIG. 14, in a semiconductor device 50, the active pattern FA may include a plurality of nanosheets 105 spaced apart from each other in the vertical direction (i.e., Z direction) and extending in the first horizontal direction (i.e., X direction), and the transistor formed by the plurality of nanosheets 105 and gate electrodes 110 may include a multi-bridge channel FET (MBCFET).

In some cases, the semiconductor device may include a ForkFET in which n-type and p-type transistors have a close structure as nanosheets for p-type transistors and nanosheets for n-type transistors are separated by dielectric walls.

Additionally, the semiconductor device may include a vertical FET (VFET) in which source/drain regions are spaced apart from each other in a vertical direction (i.e., Z direction) with a channel region in between and the gate electrodes surrounds the channel region.

Additionally, the semiconductor device may include a complementary FET (CFET), a negative FET (NCFET), a carbon nanotube (CNT) FET, or the like, and the semiconductor device may also include a bipolar junction transistor and another three-dimensional transistor.

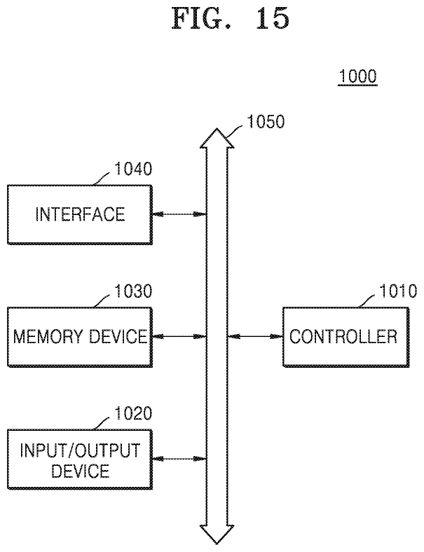

FIG. 15 is a block diagram illustrating a system including a semiconductor device according to an embodiment.

Referring to FIG. 15, the system 1000 includes a controller 1010, an input/output device 1020, a memory device 1030, an interface 1040, and a bus 1050.

The system 1000 may be a mobile system or a system for transmitting or receiving information. According to some embodiments, the mobile system may be a portable computer, a web tablet, a mobile phone, a digital music player, or a memory card.

The controller 1010 is used for controlling an execution program in the system 1000 and may include a microprocessor, a digital signal processor, a microcontroller, or a similar device.

The input/output device 1020 may be used to input or output data of the system 1000. The system 1000 may be connected to an external device, such as a personal computer or network, using the input/output device 1020, and may exchange data with the external device. The input/output device 1020 may be, for example, a touch screen, a touch pad, a keyboard, or a display.

The memory device 1030 may store data for an operation of the controller 1010 or may store data processed by the controller 1010. The memory device 1030 may include any one of the semiconductor devices 10, 20, 30, 40, and 50.

The interface 1040 may be a data transmission path between the system 1000 and an external device. The controller 1010, the input/output device 1020, the memory device 1030, and the interface 1040 may communicate with each other through the bus 1050.

While the inventive concept has been particularly shown and described with reference to embodiments thereof, it will be understood that various changes in form and details may be made therein without departing from the spirit and scope of the following claims.

The processes discussed above are intended to be illustrative and not limiting. One skilled in the art would appreciate that the steps of the processes discussed herein may be omitted, modified, combined, and/or rearranged, and any additional steps may be performed without departing from the scope of the invention. More generally, the above disclosure is meant to be exemplary and not limiting. Only the claims that follow are meant to set bounds as to what the present invention includes. Furthermore, it should be noted that the features and limitations described in any one embodiment may be applied to any other embodiment herein, and flowcharts or examples relating to one embodiment may be combined with any other embodiment in a suitable manner, done in different orders, or done in parallel. In addition, the systems and methods described herein may be performed in real time. It should also be noted, the systems and/or methods described above may be applied to, or used in accordance with, other systems and/or methods.

What is claimed is:

1. A semiconductor device comprising:
a substrate having a first region and a second region spaced apart from each other;
a plurality of first gate structures disposed in the first region, spaced apart from each other in a first horizontal direction, extending in a second horizontal direction perpendicular to the first horizontal direction, and having a first width;
a plurality of second gate structures disposed in the second region, spaced apart from each other in the first horizontal direction, extending in the second horizontal direction, and having a second width greater than the first width;
a plurality of single diffusion breaks arranged between the plurality of first gate structures and extending in the second horizontal direction; and
a plurality of dummy diffusion breaks arranged between the first region and the second region, extending in the second horizontal direction, and including a same material as the single diffusion breaks.

2. The semiconductor device of claim 1, wherein a width of each of the dummy diffusion breaks in the first horizontal direction is greater than or equal to a width of each of the single diffusion breaks in the first horizontal direction.

3. The semiconductor device of claim 1, wherein a length of each of the dummy diffusion breaks in a vertical direction perpendicular to the first horizontal direction and the second horizontal direction is less than a length of each of the single diffusion breaks in the vertical direction.

4. The semiconductor device of claim 3, wherein:
a level of a bottom surface of the dummy diffusion breaks is higher than a level of a top surface of the substrate in the vertical direction, and
a level of a bottom surface of the single diffusion breaks is lower than the level of the top surface of the substrate in the vertical direction.

5. The semiconductor device of claim 1, further comprising an interlayer insulating layer, wherein:
the interlayer insulating layer surrounds each of the single diffusion breaks and each of the dummy diffusion breaks in the first horizontal direction, and
a material of the dummy diffusion breaks has a lower etch rate than a material of the interlayer insulating layer.

6. The semiconductor device of claim 1, wherein:
a level of a top surface of the first gate structures is substantially equal to a level of a top surface of the dummy diffusion breaks in a vertical direction perpendicular to the first horizontal direction and the second horizontal direction, and
a level of a top surface of the second gate structures is lower than the level of the top surface of the dummy diffusion breaks in the vertical direction.

7. The semiconductor device of claim 6, further comprising an interlayer insulating layer, wherein:
the interlayer insulating layer surrounds each of the first gate structures and each of the second gate structures in the first horizontal direction, and
the level of the top surface of the interlayer insulating layer around the first gate structures is higher than the level of the top surface of the interlayer insulating layer around the second gate structures in the vertical direction.

8. The semiconductor device of claim 1, wherein the plurality of dummy diffusion breaks are separated by a constant distance in the first horizontal direction.

9. The semiconductor device of claim 1, further comprising a fin-type active pattern that is arranged below the first gate structures in a vertical direction perpendicular to the first horizontal direction and the second horizontal direction.

10. The semiconductor device of claim 1, further comprising a plurality of stacked nanosheets that are arranged below the first gate structures in a vertical direction perpendicular to the first horizontal direction and the second horizontal direction.

11. A semiconductor device comprising:
a substrate having a first region, a second region, and a dummy region arranged between the first region and the second region and divided into a plurality of zones;
a plurality of first gate structures disposed in the first region, spaced apart from each other in a first horizontal direction, extending in a second horizontal direction perpendicular to the first horizontal direction, and having a first width;
a plurality of second gate structures disposed in the second region, spaced apart from each other in the first horizontal direction, extending in the second horizontal direction, and having a second width greater than the first width;
a plurality of single diffusion breaks arranged between the plurality of first gate structures and extending in the second horizontal direction; and
a plurality of dummy diffusion breaks arranged in the dummy region, extending in the second horizontal direction, and having different lengths in the second horizontal direction in the plurality of zones.

12. The semiconductor device of claim 11, wherein:
a width of each of the plurality of dummy diffusion breaks in the first horizontal direction is same, and
the plurality of dummy diffusion breaks are separated by a constant distance in the first horizontal direction.

13. The semiconductor device of claim 11, wherein the dummy diffusion breaks include a same material as the single diffusion breaks.

14. The semiconductor device of claim 13, further comprising an interlayer insulating layer, wherein:
the interlayer insulating layer surrounds each of the single diffusion breaks and each of the dummy diffusion breaks in the first horizontal direction, and
a material of the dummy diffusion breaks has a lower etch rate than a material of the interlayer insulating layer.

15. The semiconductor device of claim 14, wherein:
the material of the interlayer insulating layer is silicon oxide, and
the material of the dummy diffusion breaks is silicon nitride.

16. A semiconductor device comprising:
a substrate having a first region, a second region, and a dummy region arranged between the first region and the second region;
a plurality of first active patterns disposed in the first region and extending in a first horizontal direction;
a plurality of first gate structures disposed in the first region, extending in a second horizontal direction perpendicular to the first horizontal direction, and having a first width, wherein the plurality of first gate structures crosses the first active patterns in the first region;
a plurality of second active patterns disposed in the second region and extending in the first horizontal direction;
a plurality of second gate structures disposed in the second region, extending in the second horizontal direction, and having a second width greater than the first width, wherein the plurality of second gate structures crosses the second active patterns in the second region;
a plurality of first recesses arranged between the plurality of first gate structures and spaced apart from each other in the first horizontal direction;
a plurality of single diffusion breaks arranged in the plurality of first recesses and extending in the second horizontal direction;
a plurality of dummy diffusion breaks arranged in the dummy region, extending in the second horizontal direction, and including a same material as the single diffusion breaks; and
an interlayer insulating layer surrounding each of the first gate structures, the second gate structures, the single diffusion breaks, and the dummy diffusion breaks.

17. The semiconductor device of claim 16, wherein
a level of the interlayer insulating layer in the first region is higher than a level of the interlayer insulating layer in the dummy region in a vertical direction perpendicular to the first horizontal direction and the second horizontal direction, and
a level of the interlayer insulating layer in the second region is lower than the level of the interlayer insulating layer in the dummy region in the vertical direction.

18. The semiconductor device of claim 16, wherein
the plurality of single diffusion breaks extends in the substrate through the interlayer insulating layer, and
the plurality of dummy diffusion breaks extends into a portion of the interlayer insulating layer without passing through the interlayer insulating layer.

19. The semiconductor device of claim 16, wherein
the plurality of single diffusion breaks and the plurality of dummy diffusion breaks extend in the substrate through the interlayer insulating layer, and
a level of a bottom surface of the single diffusion breaks is higher than a level of a bottom surface of the dummy diffusion breaks in a vertical direction perpendicular to the first horizontal direction and the second horizontal direction.

20. The semiconductor device of claim 16, wherein the plurality of single diffusion breaks are formed by performing a replacement process on at least one of the plurality of first gate structures.
